(19) United States
(12) Patent Application Publication
(10) Pub. No.: US 2026/0068660 A1
(43) Pub. Date: Mar. 5, 2026

(54) PACKAGE HEAT DISSIPATION

(71) Applicant: TEXAS INSTRUMENTS INCORPORATED, Dallas, TX (US)

(72) Inventors: Jonathan Andrew MONTOYA, Dallas, TX (US); Jason B. COLTE, La Trinidad (PH); John Carlo C. MOLINA, Limay (PH)

(21) Appl. No.: 18/821,823

(22) Filed: Aug. 30, 2024

(51) Int. Cl. H01L 23/367; H01L 23/31; H01L 23/373; H01L 23/538; H01L 25/16

(52) U.S. Cl. CPC H01L 23/3675

(57) ABSTRACT

In examples, an electronic device comprises a multi-layer substrate including multiple metal layers and a solid dielectric layer positioned between the multiple metal layers, the multi-layer substrate including first and second contacts coupled to the multiple metal layers. The electronic device comprises a semiconductor die having a first surface coupled to the multi-layer substrate and a second surface opposite the first surface, and a passive component having a conductive terminal coupled to the first contact. The electronic device includes a first thermally conductive component contacting the second surface of the semiconductor die and contacting the second contact, the first thermally conductive component positioned between the semiconductor die and the passive component. The electronic device includes a second thermally conductive component coupled to the first thermally conductive component, the second thermally conductive component circumscribing the passive component.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, an electronic device comprises a multi-layer substrate including multiple metal layers and a solid dielectric layer positioned between the multiple metal layers, the multi-layer substrate including first and second contacts coupled to the multiple metal layers. The electronic device comprises a semiconductor die having a first surface coupled to the multi-layer substrate and a second surface opposite the first surface, and a passive component having a conductive terminal coupled to the first contact. The electronic device includes a first thermally conductive component contacting the second surface of the semiconductor die and contacting the second contact, the first thermally conductive component positioned between the semiconductor die and the passive component. The electronic device includes a second thermally conductive component coupled to the first thermally conductive component, the second thermally conductive component circumscribing the passive component.

In examples, a method for manufacturing an electronic device comprises obtaining a multi-layer substrate having multiple metal layers and a dielectric material between the multiple metal layers. A semiconductor die and multiple contacts are coupled to the multi-layer substrate. A first thermally conductive component is coupled to the semiconductor die and to a first subset of the multiple contacts, and a second thermally conductive component is coupled to the first thermally conductive component. The second thermally conductive component has first and second members in parallel with each other and extends vertically away from the multi-layer substrate. A third member extends between the first and second members. The second thermally conductive component circumscribes a hollow volume. The method also includes positioning an inductor within the hollow volume and coupling the inductor to a second subset of the multiple contacts.

### BRIEF DESCRIPTION OF THE DRAWINGS

FIG. 1 is a block diagram of a system including an electronic device in accordance with various examples.

FIGS. 2A-2E are perspective, perspective, profile, profile, and top-down views of an electronic device in accordance with various examples.

FIGS. 3A-3D are perspective, top-down, profile, and profile views of an electronic device with heat-dissipating fins, in accordance with various examples.

FIGS. 4A-4D are perspective, profile, profile, and top-down views of portions of an electronic device in accordance with various examples.

FIGS. 5A-5D are perspective, top-down, profile, and profile views of portions of an electronic device in accordance with various examples.

FIGS. 6A-6D are perspective, top-down, profile, and profile views of portions of an electronic device in accordance with various examples.

FIGS. 7A-7C are perspective, cross-sectional, and bottom-up views of portions of an electronic device in accordance with various examples.

FIGS. 8A-8E depict the effective heat dissipation achieved by electronic devices described herein, in accordance with various examples.

FIG. 9 is a flow diagram of a method for manufacturing an electronic device in accordance with various examples.

### DETAILED DESCRIPTION

Some types of semiconductor packages include passive components, such as inductors. These semiconductor packages may also include other components, such as semiconductor dies. The semiconductor dies, as well as other components of the semiconductor package, can generate substantial amounts of heat. The semiconductor package can be damaged if the heat is not expelled. Accordingly, in many applications, the passive component is manufactured to include heat dissipating members that expel heat generated by the semiconductor die, the passive component, and/or other components in the semiconductor package. Although such heat dissipating members may be modestly effective in expelling heat, the heat dissipating members increase the design and manufacturing complexity of the passive components. Specifically, passive components must be engineered to include such heat dissipating members, thereby undesirably adding time, complexity, and cost. Furthermore, the requirement to include a heat dissipating member as part of the passive component reduces the flexibility with which engineers may design the passive component.

This disclosure describes various examples of an electronic device that mitigates the technical challenges described above by including heat dissipating members that are separate from the passive components of the electronic device. The primary heat dissipation pathways of the electronic device do not pass through the passive components. Because the passive components are no longer required to incorporate heat dissipation members, engineers enjoy significantly increased flexibility in designing the passive components. Substantial technical advances in passive component design may be realized by omitting heat dissipation members from the passive components. Manufacturing complexity, time, and costs are likewise reduced.

In examples, an electronic device comprises a multi-layer substrate having first and second substrate surfaces, multiple metal layers between the first and second substrate surfaces, and a solid dielectric layer in between the multiple metal layers. The electronic device also comprises first and second semiconductor dies coupled to the multi-layer substrate and first, second, third, and fourth pairs of contacts coupled to the multi-layer substrate. The electronic device also includes a mold compound covering the second substrate surface, where the first and second semiconductor dies and the first, second, third, and fourth pairs of contacts are exposed to a surface of the mold compound. The electronic device also includes a first thermally conductive component having first and second parallel members and a third member extending between the first and second parallel members, with the first and second parallel members coupled to the first and second pairs of contacts. The electronic device also comprises a second thermally conductive component coupling the third member to the first and second semiconductor dies, and first and second inductors coupled to the third and fourth pairs of contacts. The electronic device further comprises a third thermally conductive component having first and second members coupled to the first and second parallel members, respectively, with the first and second members of the third thermally conductive component extending away from the multi-layer substrate in a vertical direction, and the third thermally conductive component having a third member extending between distal ends of the first and second members of the third thermally conductive component.

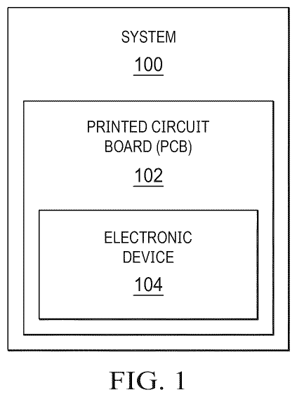

FIG. 1 is a block diagram of a system including an electronic device in accordance with various examples. Specifically, FIG. 1 depicts a block diagram of a system 100 containing a printed circuit board (PCB) 102. An electronic device 104 is coupled to the PCB 102. The system 100 may be any suitable type of system, such as an automobile, an aircraft, a watercraft, a spacecraft, a video game console, an arcade video game unit, a smartphone, an entertainment device, an appliance, a laptop computer, a desktop computer, a tablet, a notebook, or any other suitable type of system or device. Various examples of the electronic device 104 are provided below. In at least some such examples, the electronic device 104 performs one or more actions according to the capabilities of a semiconductor die therein, and such actions may include the use of a passive component, such as an inductor, included within the electronic device 104. The heat dissipation features of the electronic device 104 facilitate the expulsion of heat from the electronic device 104 while expanding the flexibility and options with which an engineer or other person may design and implement the passive component of the electronic device 104. In this way, an engineer or other person may readily swap passive components of different designs into and out of the electronic device 104 without having to invest time and financial resources in ensuring the passive component includes adequate heat dissipation capabilities and complies with heat dissipation design specifications.

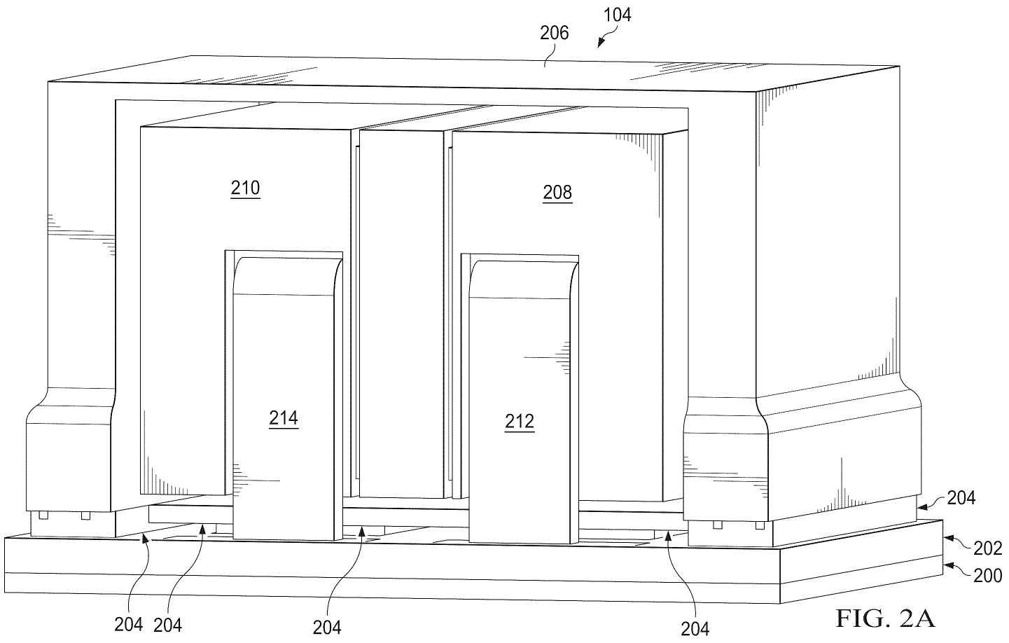

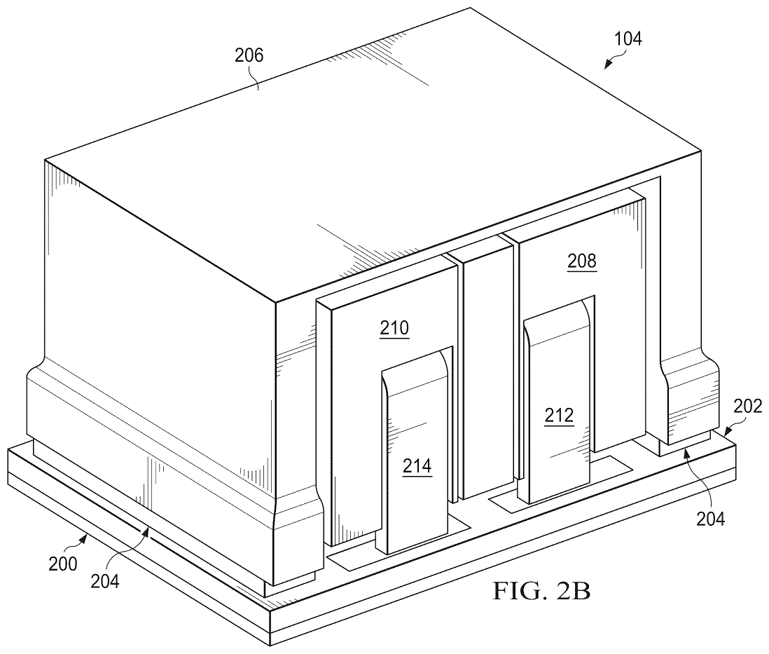

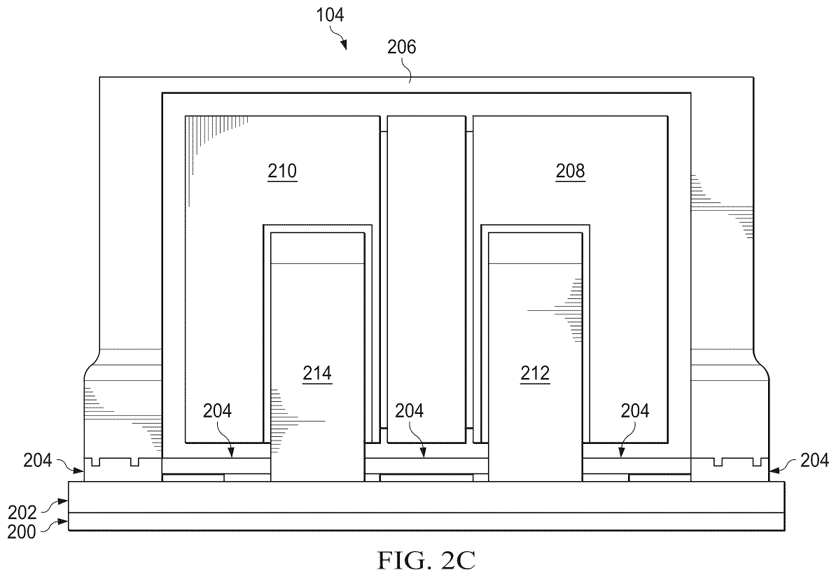

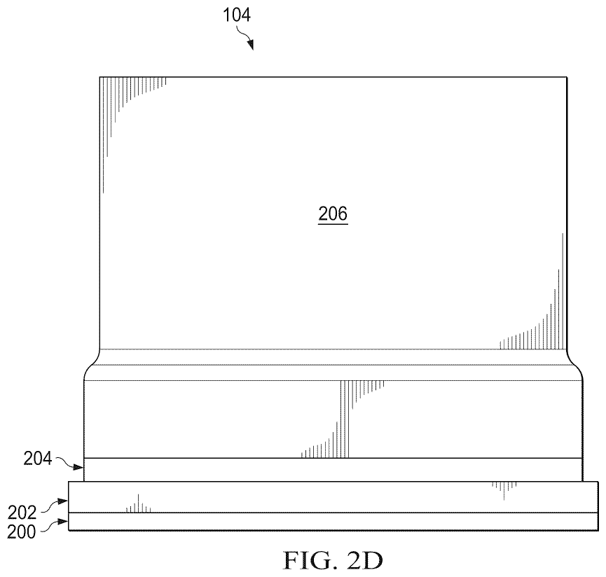

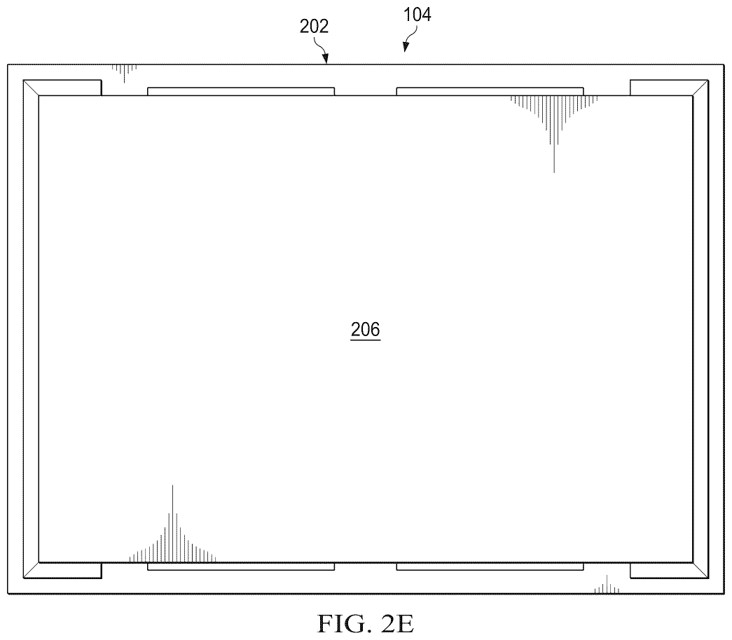

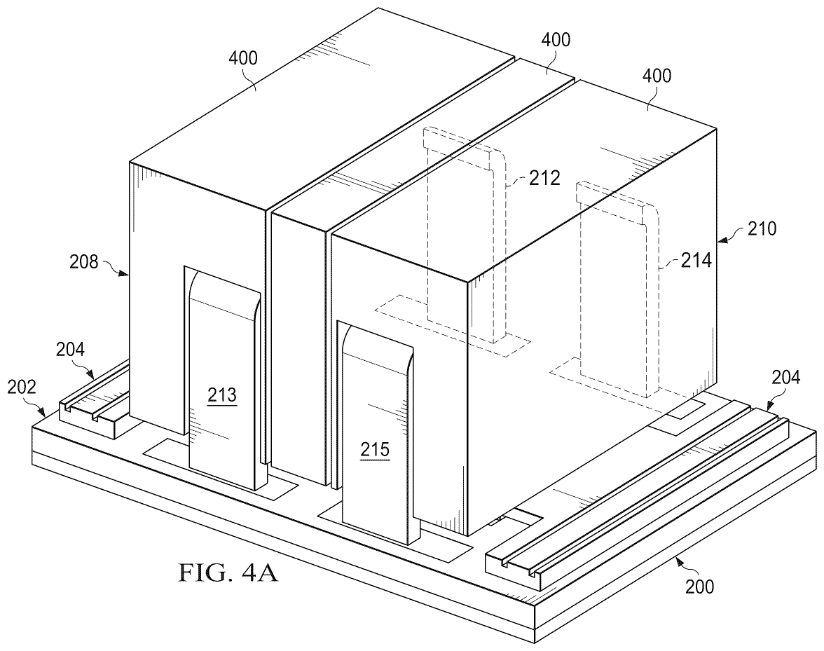

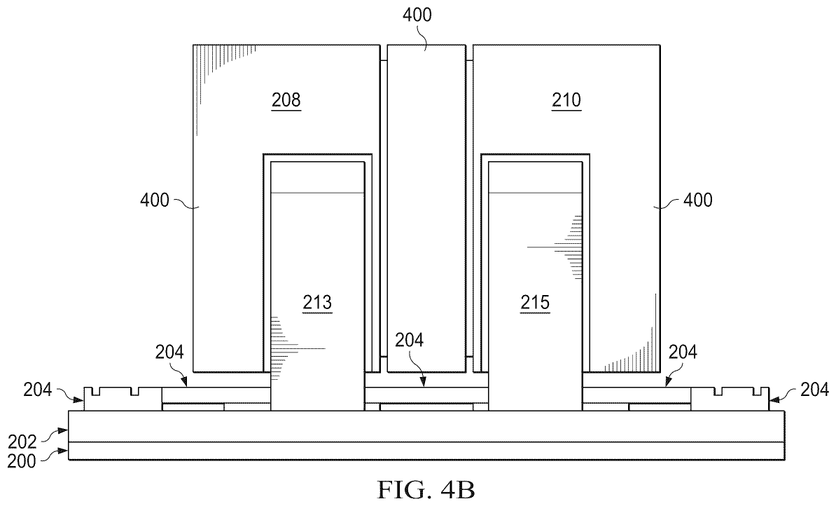

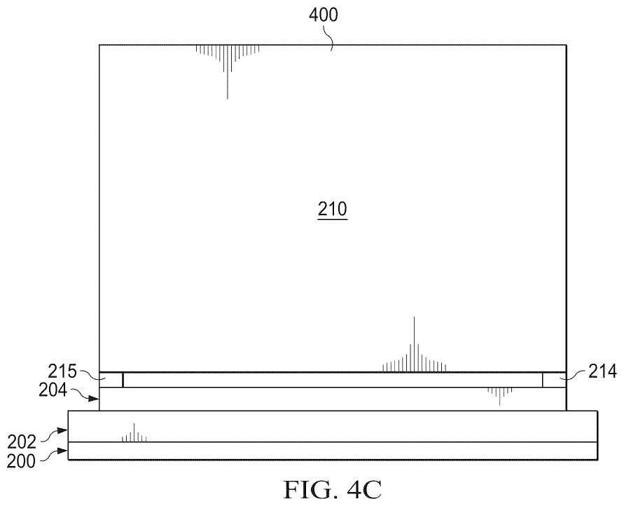

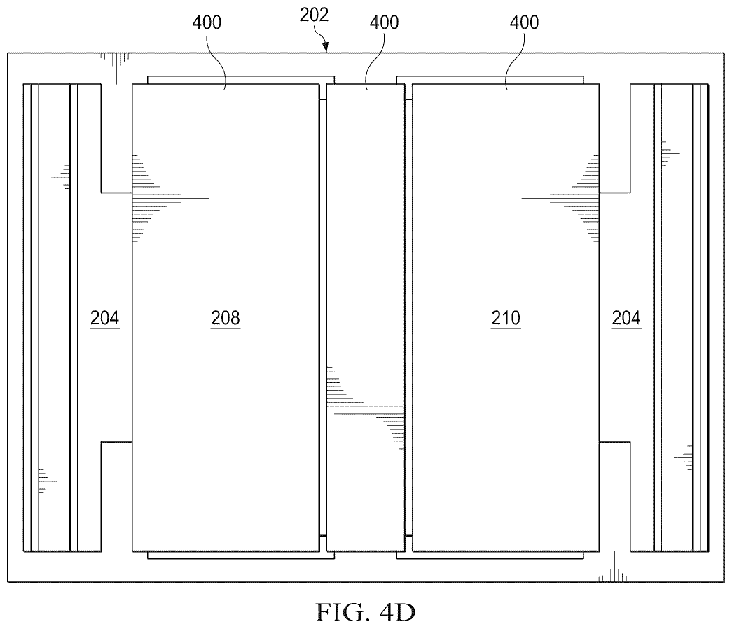

FIGS. 2A-2E are perspective, perspective, profile, profile, and top-down views of an example electronic device 104. The example electronic device 104 includes a substrate 200, circuitry 202 coupled to the substrate 200, and a thermally conductive component 204 coupled to the circuitry 202. The example electronic device 104 also comprises a thermally conductive component 206 coupled to the thermally conductive component 204. The example electronic device 104 further includes passive components 208 and 210. The passive component 208 is coupled to the circuitry 202 via conductive terminals 212 and 213 (with conductive terminal 213 being visible in at least FIG. 4A). The passive component 210 is coupled to the circuitry 202 via conductive terminals 214 and 215 (with conductive terminal 215 being visible in at least FIG. 4A). Each of the passive components 208, 210 extends away from the substrate 200 in a direction that is orthogonal to a plane in which the substrate 200 lies.

In examples, the substrate 200 is a multi-layer substrate comprising multiple metal layers and one or more dielectric layers in between the multiple metal layers. Stated in another way, the multiple metal layers may contact dielectric material that is present in various portions of the substrate 200. (The term “contact,” as used herein, means direct physical contact.) The dielectric material may include any solid dielectric, such as a build-up film (e.g., AJINOMOTO® build-up film (ABF)). Thus, in such examples, the substrate 200 is not a PCB. The multiple metal layers form a network of metal layers and terminate at the top and bottom surfaces of the substrate 200 at metal contacts. The metal contacts make the network of metal layers within the substrate 200 accessible to components outside the substrate 200, such as the conductive terminals 212-215 and the PCB 102 (FIG. 1), to which the substrate 200 may be coupled. In some examples, the substrate 200 is a PCB, in which the dielectric material is air. Other types of substrates are contemplated and included in the scope of this disclosure.

The circuitry 202 includes any suitable type of circuitry, such as one or more semiconductor dies, one or more passive components (e.g., capacitors, inductors), etc. One or more of the various components included in the circuitry 202 may couple to one or more other such components either directly or through metal layers of the substrate 200 (e.g., by coupling to the aforementioned metal contacts on a top surface of the substrate 200). The circuitry 202 is covered by a mold compound or other protective material. One or more components within the circuitry 202 may be exposed to a top surface of the mold compound so as to facilitate coupling to components outside of the circuitry 202.

The thermally conductive component 204 is coupled to components within the circuitry 202, such as to one or more semiconductor dies that are exposed to a surface of the mold compound covering the circuitry 202. The thermally conductive component 204 is coupled to metal contacts in the circuitry 202 that are coupled to the metal layers in the substrate 200 and ultimately to contacts on a bottom surface of the substrate 200, thereby providing a heat dissipation pathway downward through the substrate 200. Because the thermally conductive component 204 is coupled to the one or more semiconductor dies (e.g., through a solder member or other thermally conductive material), the thermally conductive component 204 carries heat away from the semiconductor die(s) and toward the thermally conductive component 206.

The thermally conductive component 206 is coupled to the thermally conductive component 204 and carries heat away from the thermally conductive component 204 in a vertical direction away from the thermally conductive component 204. The thermally conductive component 206 has two vertical members extending away from the thermally conductive component 204 approximately in parallel with each other. Each of these vertical members extends approximately parallel to a corresponding vertical surface of a corresponding passive component 208, 210. A horizontal member extends between and couples to both of the two vertical members. In this way, the vertical members and the horizontal member circumscribe the passive components 208 and 210. In examples, the passive components 208 and 210 contact interior surfaces of the vertical and horizontal members of the thermally conductive component 206, and in other examples, a gap exists between one or more of such interior surfaces and one or more of the passive components 208 and/or 210. In the latter examples, the gap is at least 200 microns, with gaps lower than this range being disadvantageous because component assembly becomes prohibitively difficult. The vertical and horizontal members of the thermally conductive component 206 range in thickness from 200 microns to 800 microns, with thicknesses below this range being disadvantageous because thermal transfer is unacceptably inefficient, and with thicknesses above this range being disadvantageous because formation of the thermally conductive component 206 becomes prohibitively difficult. In examples, a heat dissipation device, such as a heat exchanger, may be coupled to an exterior surface of the horizontal member of the thermally conductive component 206 to facilitate heat expulsion from the electronic device 104.

The thermally conductive component 206 may be composed of any suitable thermally conductive material, such as copper or aluminum, or another metal or alloy. In examples, the thermally conductive component 206 is coated with an inert finish.

The passive components 208 and 210 may be any suitable type of passive components, such as resistors, inductors and/or capacitors. Example inductor types can include coil and/or staple inductors, although other types of inductors are contemplated and included in the scope of this disclosure. The conductive terminals 212-215 may be coupled to circuitry 202 so that the passive components 208 and 210 may be functionally coupled to the circuitry 202.

In some examples, during manufacture, the thermally conductive component 206 is coupled to the thermally conductive component 204 (e.g., using solder or other thermally conductive material(s)). The passive components 208, 210 may subsequently be inserted into the empty volume circumscribed by the thermally conductive component 206 and the conductive terminals 212-215 may be coupled (e.g., soldered) to the circuitry 202, for example, to conductive members exposed to a surface of the mold compound covering the circuitry 202.

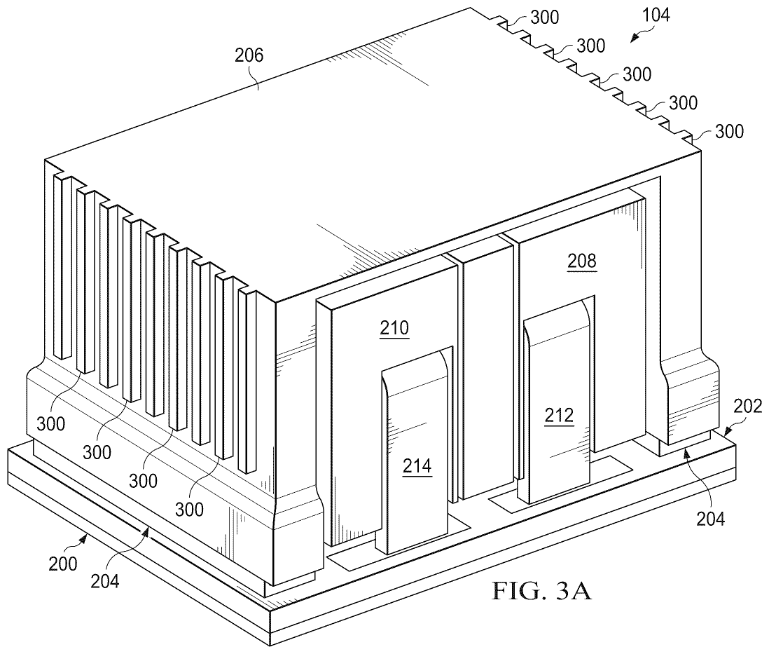

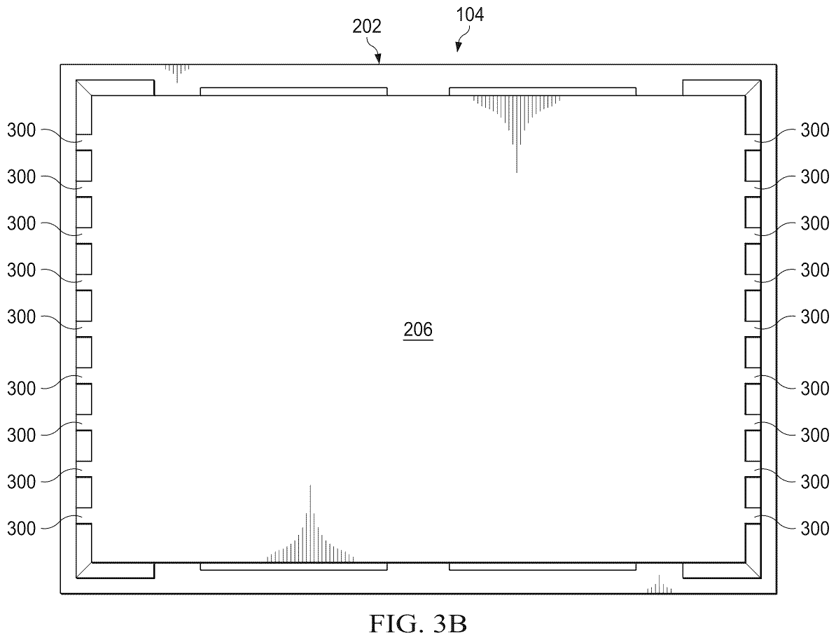

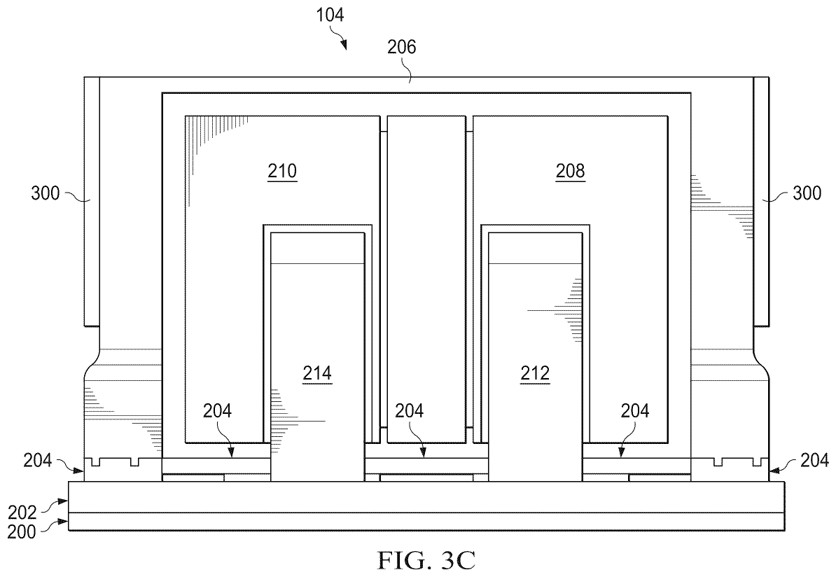

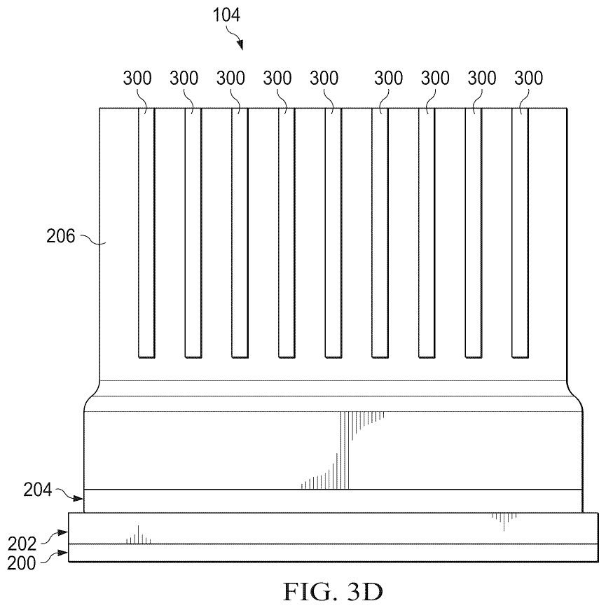

FIGS. 3A-3D are perspective, top-down, profile, and profile views of the electronic device 104 with heat-dissipating fins, in accordance with various examples. Specifically, the example electronic device 104 shown in FIGS. 3A-3D is identical to that shown in FIGS. 2A-2E, except that the thermally conductive component 206 includes multiple fins 300 on exterior surfaces of the thermally conductive component 206, as shown. The fins 300 may be composed of the same material as the thermally conductive component 206 or of a different material. In either case, the fins 300 are composed of a thermally conductive material. In examples, the fins 300 are formed from the same segment of material as the thermally conductive component 206, meaning that the thermally conductive component 206 and the fins 300 are a monolithic component. In other examples, the fins 300 are formed separately from the thermally conductive component 206 and are coupled to the thermally conductive component 206 using a thermally conductive material. The fins 300 increase the surface area through which the thermally conductive component 206 is able to expel heat. Any suitable structure(s) capable of increasing the surface area of the thermally conductive component 206 are contemplated and included in the scope of this disclosure.

FIGS. 4A-4D are perspective, profile, profile, and top-down views of portions of the electronic device 104 in accordance with various examples. More specifically, FIGS. 4A-4D show the example electronic device 104 of FIGS. 2A-2E and/or 3A-3D, except that the thermally conductive component 206 has been omitted to provide a clearer view of other structures in the electronic device 104. In examples, the passive components 208, 210 may be covered by an epoxy material 400, respectively, as shown. The passive components 208, 210 are coupled to the circuitry 202 via the conductive terminals 212-215, as described above. In examples, the epoxy materials 400 may contact each other, although the scope of this disclosure is not limited as such.

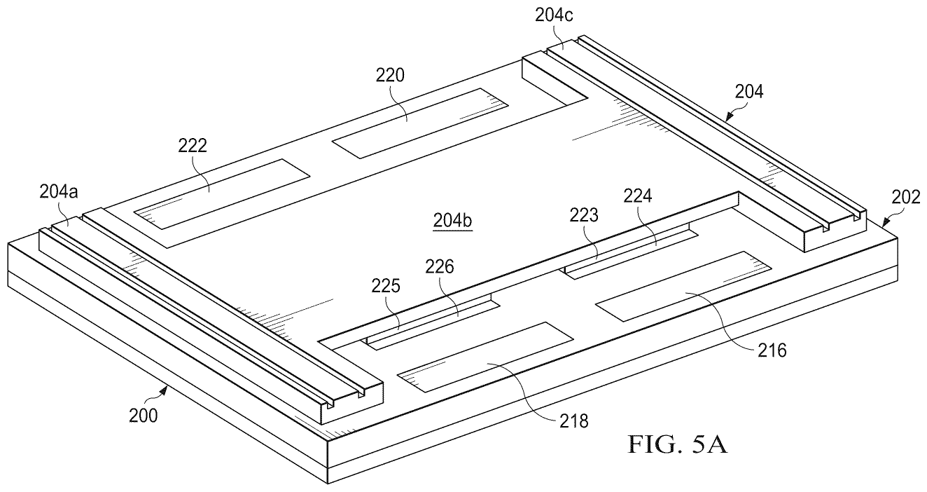

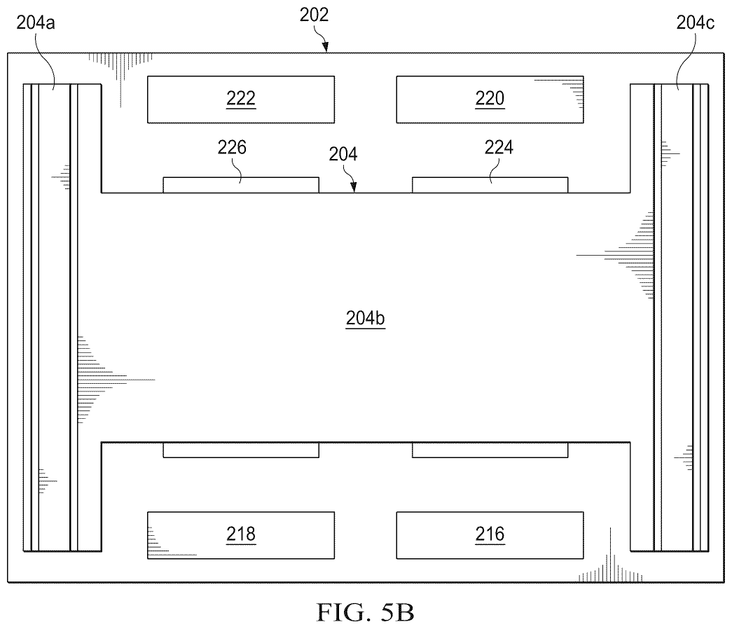

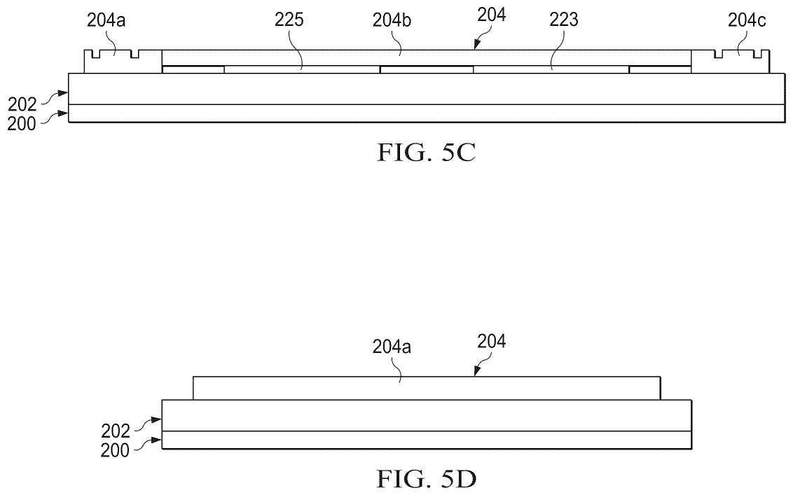

FIGS. 5A-5D are perspective, top-down, profile, and profile views of portions of the electronic device 104 in accordance with various examples. In particular, the structures shown in FIGS. 5A-5D are identical to those shown in FIGS. 4A-4D, except that the passive components 208, 210, the epoxy materials 400, and the conductive terminals 212-215 have been omitted to provide a clearer view of other structures in the electronic device 104. Accordingly, FIGS. 5A-5D show the thermally conductive component 204 in greater detail. The thermally conductive component 204 may include members 204a, 204b, and 204c, which may collectively be referred to as the thermally conductive component 204. The member 204a extends approximately parallel to the member 204c. The member 204b extends approximately orthogonal to the members 204a, 204c and is coupled to the members 204a, 204c. In examples, one or more of the members 204a-204c includes ridges or grooves to increase surface area and thus heat expulsion. Ridges or grooves in the members 204a, 204c also may facilitate more secure coupling to the thermally conductive component 206.

The members 204a-204c are composed of a thermally conductive material, such as copper, another metal, or a metal alloy. Each of the members 204a-204c has a thickness ranging from 200 microns to 1000 microns, with thicknesses below this range being disadvantageous because they are too thin to provide sufficient heat removal, and with thicknesses above this range being disadvantageous because of the additional height space consumed and because of fabrication challenges. The members 204a, 204b, and 204c are not required to have the same thickness.

In examples, the bottom surface of the member 204b either directly contacts semiconductor dies 224, 226 or indirectly contacts the semiconductor dies 224, 226 (e.g., via a solder member 223, 225 or other thermally conductive material). In examples, the bottom surface of the member 204b contacts the entire top surfaces of the semiconductor dies 224, 226. To facilitate contact, the top surfaces of the semiconductor dies 224, 226 are exposed from a top surface of the mold compound covering the circuitry 202. Contacts 216, 218, 220, and 222 are also exposed from the top surface of the mold compound covering the circuitry 202. The contacts 216, 220 couple to the conductive terminals 212, 213, respectively, and the contacts 218, 222 couple to the conductive terminals 214, 215, respectively. Any suitable material, such as solder, may be useful to establish such couplings. Additional contacts (not visible in the view of FIGS. 5A-5D) are exposed from the surface of the mold compound covering the circuitry 202 and couple to the member 204a, while additional contacts (not visible in the view of FIGS. 5A-5D) are exposed from the surface of the mold compound covering the circuitry 202 and couple to the member 204c. Some or all of the contacts described herein are composed of a thermally and/or electrically conductive material, such as copper, another metal, or a metal alloy.

In some examples, the top surfaces of the members 204a-204c are approximately co-planar with each other. In other examples, the top surfaces of the members 204a and 204c are approximately co-planar with each other and the top surface of the member 204b is raised or lowered (i.e., farther from the circuitry 202 or closer to the circuitry 202, respectively) relative to the members 204a, 204c.

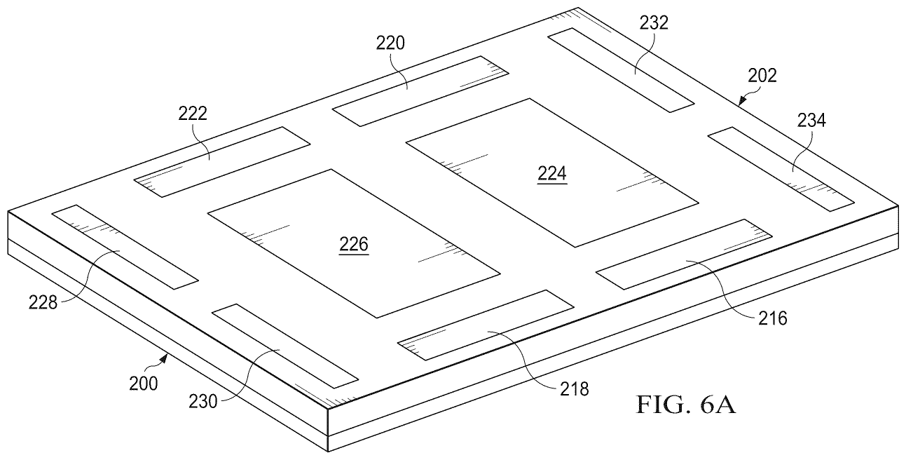

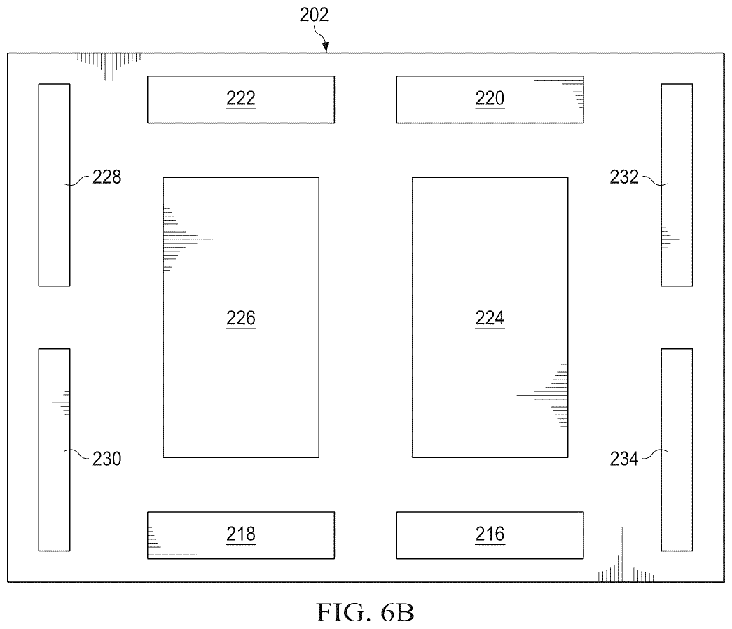

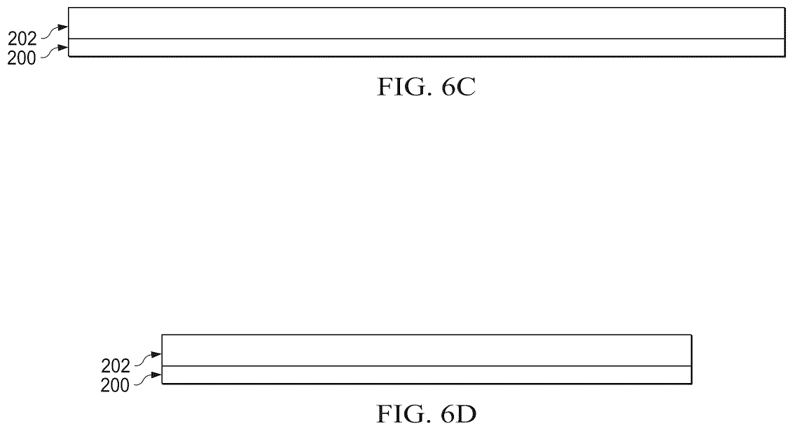

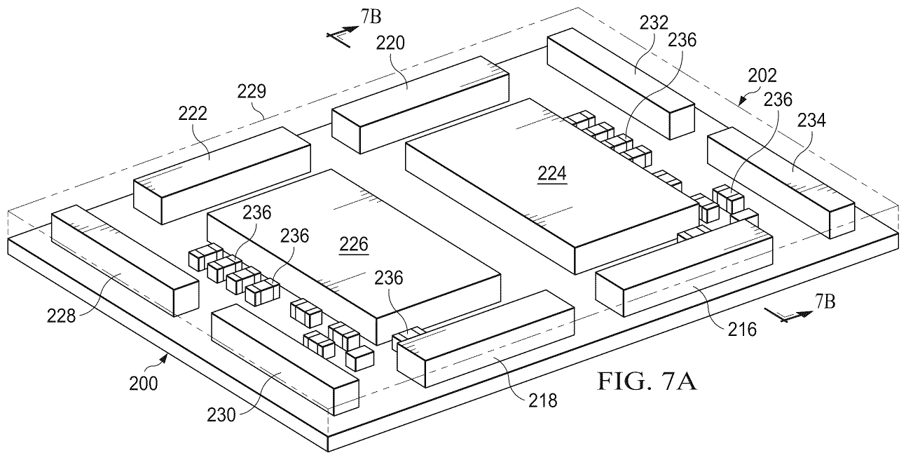

FIGS. 6A-6D are perspective, top-down, profile, and profile views of portions of the electronic device 104, in accordance with various examples. More specifically, the structures shown in FIGS. 6A-6D are identical to those shown in FIGS. 5A-5D, except that the thermally conductive component 204 has been omitted to provide a clearer view of other structures within the electronic device 104. FIGS. 6A-6D show the semiconductor dies 224, 226 exposed from the top surface of the mold compound covering the circuitry 202. Further, the contacts 216, 218, 220, and 222 are also exposed from the top surface of the mold compound covering the circuitry 202. Additionally, contacts 228, 230, 232, and 234, which are positioned under and coupled to the members 204a and 204c (FIG. 5A), are exposed from the top surface of the mold compound covering the circuitry 202. In examples, the top surfaces of the semiconductor dies 224, 226 and the top surfaces of the contacts 216, 218, 220, 222, 228, 230, 232, and 234 are approximately flush with the top surface of the mold compound covering the circuitry 202. In examples, a line extending through the pair of contacts 228, 230 is approximately orthogonal to lines extending through the pair of contacts 220, 222 and through the pair of contacts 216, 218. Similarly, a line extending through the pair of contacts 232, 234 is approximately orthogonal to lines extending through the pair of contacts 220, 222 and through the pair of contacts 216, 218. The lines extending through the pair of contacts 228, 230 and through the pair of contacts 232, 234 may be approximately parallel with each other.

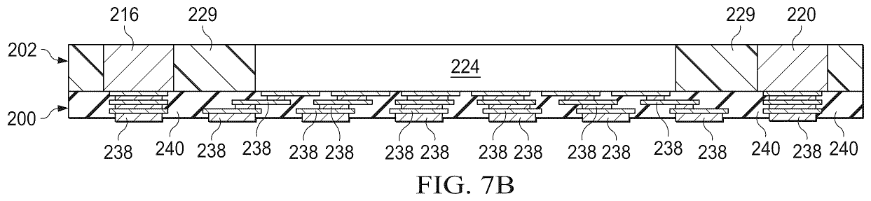

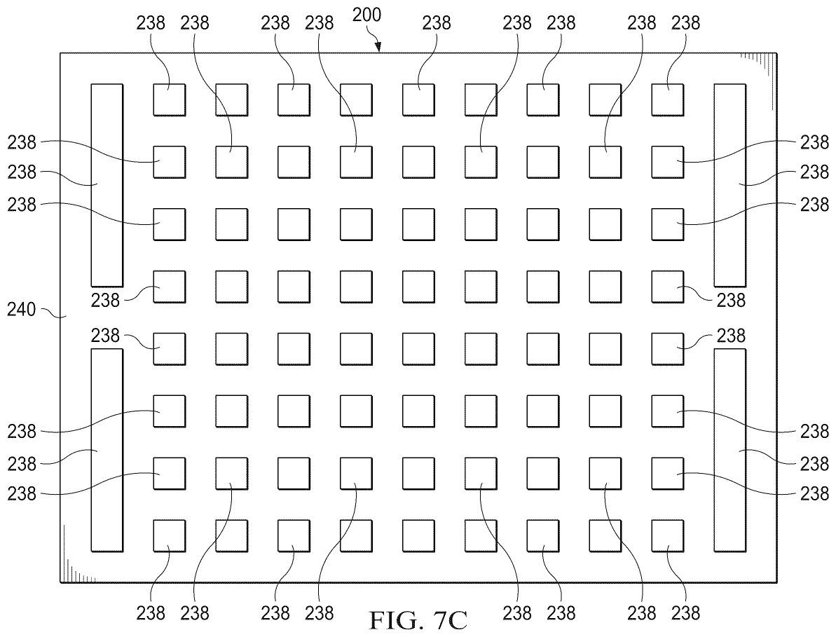

FIGS. 7A-7C are perspective, cross-sectional, and bottom-up views of portions of the electronic device 104 in accordance with various examples. Specifically, FIGS. 7A-7C depict example contents of the circuitry 202. In examples, the circuitry 202 includes the semiconductor dies 224, 226; contacts 216, 218, 220, and 222; contacts 228, 230, 232, and 234; and passive components 236 (e.g., capacitors, inductors, resistors). Some or all of the components in the circuitry 202 are coupled to the network of metal layers in the substrate 200 through contacts on the top surface of the substrate 200 that couple to the network of metal layers. Through this network of metal layers, electrical signals may be exchanged with other components, and heat may be dissipated and expelled from the electronic device 104. As shown, the contacts 216, 218, 220, 222, 228, 230, 232, and 234 may extend through a thickness of the circuitry 202 and/or the mold compound covering the circuitry 202 such that these contacts can be exposed from a top surface of the mold compound that covers the circuitry 202. A mold compound 229 at least partially covers the various structures as shown.

FIG. 7B depicts a cross-sectional view of the substrate 200 and the circuitry 202. In this particular cross-section, the circuitry 202 is shown as including the contacts 216, 220 and the semiconductor die 224. The mold compound 229 at least partially covers the contacts 216, 220 and the semiconductor die 224. The substrate 200 is depicted as including the network of metal layers 238, with a solid dielectric 240 (e.g., a build-up film, such as ABF) at least partially covering the network of metal layers 238.

FIG. 7C is a bottom-up view of the substrate 200, in which the bottom surface of the substrate 200 is visible. The network of metal layers 238 are exposed to the bottom surface of the substrate 200 and may be referred to herein as contacts. The bottom surfaces of the contacts may be approximately flush with the bottom surface of the substrate 200, as shown. First and second pairs of contacts 238 on the opposing short ends of the bottom surface of the substrate 200 are coupled to the pair of contacts 228, 230 and the pair of contacts 232, 234, respectively, through the network of metal layers 238 in the substrate 200. The various contacts on the bottom surface of the substrate 200 may be coupled to another component, such as the PCB 102 (FIG. 1). Heat expelled via the thermally conductive component 204, the contacts 228, 230, 232, 234, the network of metal layers 238, and the contacts on the bottom surface of the substrate 200, may be provided to the PCB 102 and carried away from the electronic device 104. Heat expelled via the thermally conductive component 204 and the thermally conductive component 206 may be expelled through the thermally conductive component 206 and/or a heat exchanger coupled to the thermally conductive component 206. Thus, multiple heat dissipation pathways are provided by the electronic device 104.

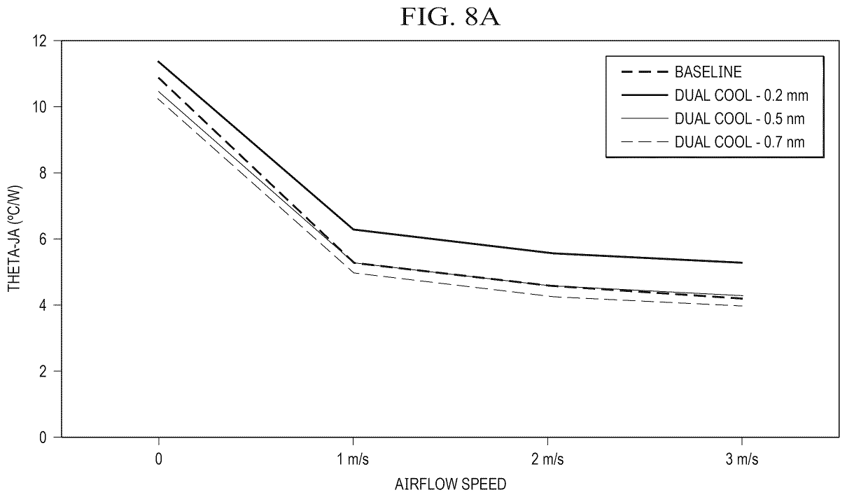

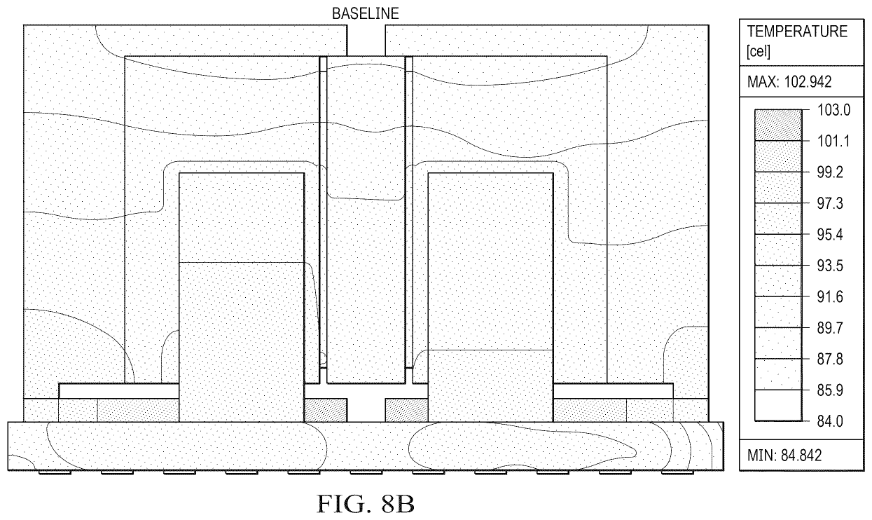

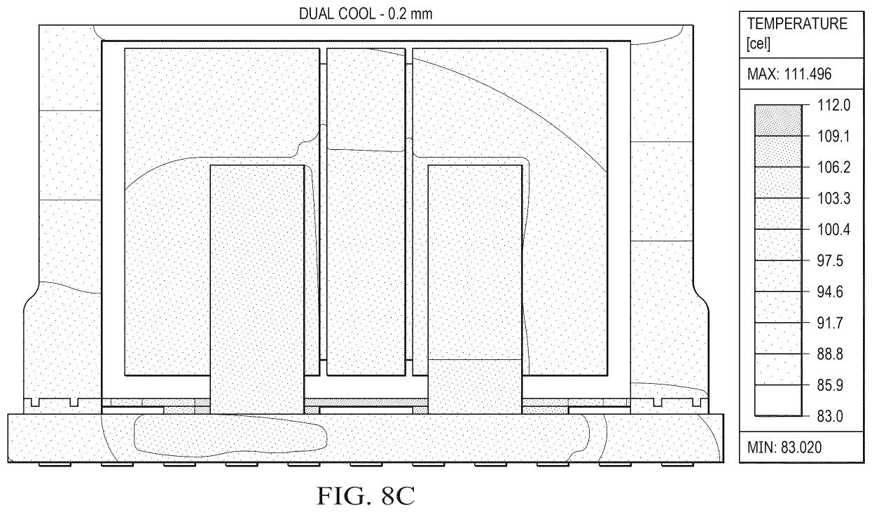

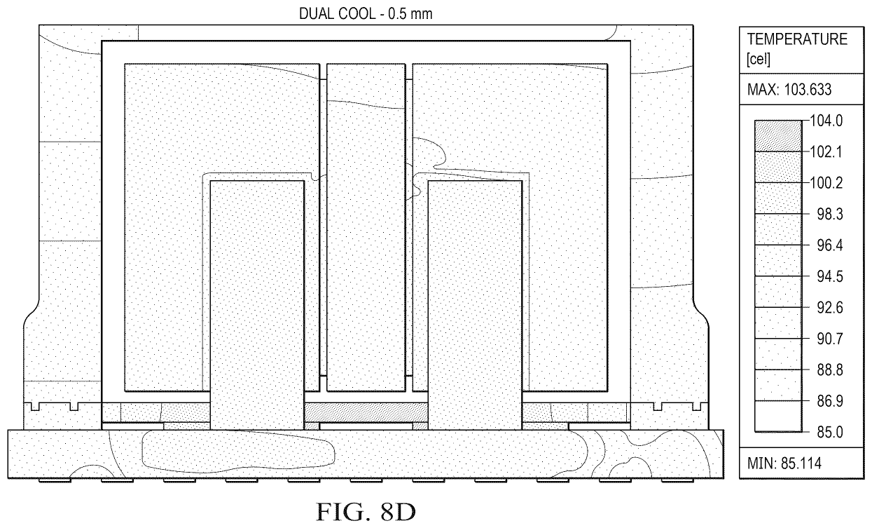

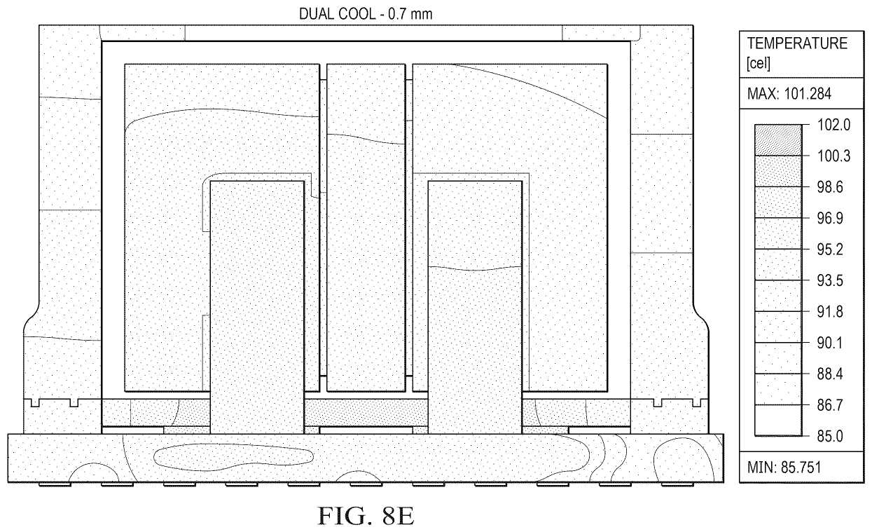

FIGS. 8A-8E depict the effective heat dissipation achieved by electronic devices described herein, in accordance with various examples. Specifically, a graph in FIG. 8A includes airflow speed through the electronic device (in meters per second) (e.g., electronic device 104) on the x-axis, and theta-JA (in degrees Celsius per Watt) on the y-axis. The graph in FIG. 8A plots four curves, which represent the theta-JA (in degrees Celsius per Watt) value as a function of airflow speed (in meters per second) in the electronic device (e.g., electronic device 104) for a baseline electronic device and for the electronic device 104 with different thicknesses of the thermally conductive component 204. As shown, heat dissipation is optimized when the thermally conductive component 204 is thickest (e.g., 0.7 mm in the example of FIG. 8A). A 0.2 mm thickness of the thermally conductive component 204 performs inferior to baseline, and a thickness of 0.5 mm is approximately equivalent to baseline performance. FIGS. 8B-8E depict the thermal dissipation performance of the baseline electronic device (FIG. 8B) and the thermal dissipation performance of the electronic device 104 for thermally conductive component 204 thicknesses of 0.2 mm, 0.5 mm, and 0.7 mm in FIGS. 8C-8E, respectively. Heat dissipation performance improves with increased thickness of the thermally conductive component 204, as shown.

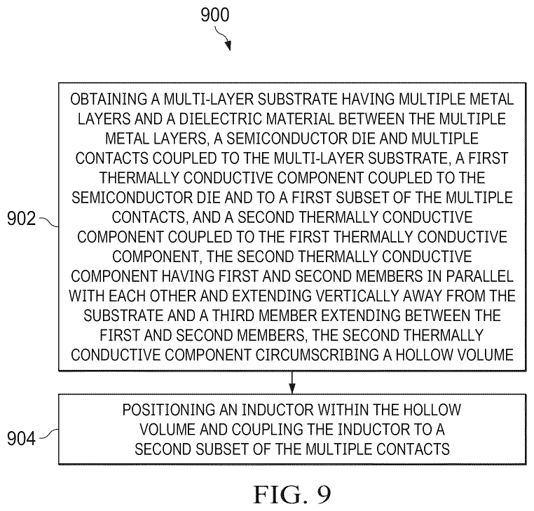

FIG. 9 is a flow diagram of a method 900 for manufacturing an electronic device in accordance with various examples. The method 900 includes obtaining a multi-layer substrate having multiple metal layers and a dielectric material between the multiple metal layers (902). A semiconductor die and multiple contacts are coupled to the multi-layer substrate (902). A first thermally conductive component is coupled to the semiconductor die and to a first subset of the multiple contacts, and a second thermally conductive component is coupled to the first thermally conductive component (902). The second thermally conductive component has first and second members in parallel with each other and extending vertically away from the multi-layer substrate, and a third member extending between the first and second members (902). The second thermally conductive component circumscribes a hollow volume (902).

The multi-layer substrate (which may be referred to as a “routable lead frame” (RLF)) may be formed by an iterative process in which a first metal layer is plated (e.g., electroplated) on a base layer, and then a film (e.g., ABF) is deposited and grinded (e.g., thinned), followed by the formation of a second metal layer and the deposition and grinding of additional film material (e.g., ABF), and so on. Vias may be formed by plating concurrently with each metal layer, or alternatively, vias may be formed by plating in between successive metal layers.

The method 900 may also include positioning an inductor or other passive component within the hollow volume and coupling the inductor to a second subset of the multiple contacts (904).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through a construction and/or layout of hardware components and interconnections of the device, etc.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. An electronic device, comprising:
a multi-layer substrate including multiple metal layers and a solid dielectric layer positioned between the multiple metal layers, the multi-layer substrate including first and second contacts coupled to the multiple metal layers;
a semiconductor die having a first surface coupled to the multi-layer substrate and a second surface opposite the first surface;
a passive component having a conductive terminal coupled to the first contact;
a first thermally conductive component contacting the second surface of the semiconductor die and contacting the second contact, the first thermally conductive component positioned between the semiconductor die and the passive component; and
a second thermally conductive component coupled to the first thermally conductive component, the second thermally conductive component circumscribing the passive component.

2. The electronic device of claim 1, wherein the first thermally conductive component contacts an entirety of the second surface of the semiconductor die.

3. The electronic device of claim 1, wherein the passive component extends away from the substrate in a direction that is orthogonal to a plane in which the multi-layer substrate lies.

4. The electronic device of claim 3, wherein the passive component includes a first surface extending away from the multi-layer substrate and a second surface extending approximately parallel with the multi-layer substrate, and wherein the second thermally conductive component includes a first member that extends approximately parallel to the first surface of the passive component and a second member that extends approximately parallel to the second surface of the passive component.

5. The electronic device of claim 4, wherein the first member of the second thermally conductive component includes multiple fins.

6. The electronic device of claim 1, wherein the conductive terminal is a first conductive terminal and wherein the passive component includes a second conductive terminal coupled to a third contact of the multi-layer substrate, the first and third contacts configured to supply an electrical signal through the passive component.

7. The electronic device of claim 1, wherein the first thermally conductive component includes first and second members extending approximately parallel to each other and a third member extending between and coupled to the first and second members of the first thermally conductive component.

8. The electronic device of claim 7, wherein the third member of the first thermally conductive component contacts the second surface of the semiconductor die, the first member of the first thermally conductive component coupled to the second contact, and the second member of the first thermally conductive component coupled to a fourth contact of the multi-layer substrate.

9. The electronic device of claim 8, wherein the second and fourth contacts of the multi-layer substrate are coupled to the multiple metal layers such that the multiple metal layers are configured to convey heat through a thickness of the multi-layer substrate.

10. The electronic device of claim 1, wherein the multi-layer substrate is not a printed circuit board (PCB).

11. The electronic device of claim 1, wherein the solid dielectric layer includes a build-up film.

12. An electronic device, comprising:
a multi-layer substrate having first and second substrate surfaces, multiple metal layers between the first and second substrate surfaces, and a solid dielectric layer in between the multiple metal layers;
first and second semiconductor dies coupled to the multi-layer substrate;
first, second, third, and fourth pairs of contacts coupled to the multi-layer substrate;
a mold compound covering the second substrate surface, wherein the first and second semiconductor dies and the first, second, third, and fourth pairs of contacts are exposed from a surface of the mold compound;
a first thermally conductive component having first and second parallel members and a third member extending between the first and second parallel members, the first and second parallel members coupled to the first and second pairs of contacts;
a second thermally conductive component coupling the third member to the first and second semiconductor dies;
first and second passive components coupled to the third and fourth pairs of contacts; and
a third thermally conductive component having first and second members coupled to the first and second parallel members, respectively, the first and second members of the third thermally conductive component extending away from the multi-layer substrate in a vertical direction, and the third thermally conductive component having a third member extending between distal ends of the first and second members of the third thermally conductive component.

13. The electronic device of claim 12, wherein the first and second members of the third thermally conductive component have outer surfaces and fins on the outer surfaces.

14. The electronic device of claim 12, wherein a first line extending through the first pair of contacts is approximately perpendicular to a second line extending through the third pair of contacts.

15. The electronic device of claim 12, wherein the first and second parallel members include ridges coupled to the first and second members of the third thermally conductive component.

16. The electronic device of claim 12, wherein the solid dielectric layer includes a build-up film.

17. The electronic device of claim 12, wherein the third thermally conductive component comprises copper or aluminum.

18. The electronic device of claim 12, wherein the third thermally conductive component is coated with an inert finish.

19. A method for manufacturing an electronic device, comprising:
obtaining a multi-layer substrate having multiple metal layers and a dielectric material between the multiple metal layers, a semiconductor die and multiple contacts coupled to the multi-layer substrate, a first thermally conductive component coupled to the semiconductor die and to a first subset of the multiple contacts, and a second thermally conductive component coupled to the first thermally conductive component, the second thermally conductive component having first and second members in parallel with each other and extending vertically away from the multi-layer substrate and a third member extending between the first and second members, the second thermally conductive component circumscribing a hollow volume; and
positioning an inductor within the hollow volume and coupling the inductor to a second subset of the multiple contacts.

20. The method of claim 19, wherein the first thermally conductive component includes first and second parallel members coupled to the first subset of the multiple contacts and a third member extending between the first and second parallel members.

21. The method of claim 20, wherein the third member is coupled to the semiconductor die.

22. The method of claim 19, wherein the multi-layer substrate includes a first surface facing the first thermally conductive component and a second surface opposite the first surface, the second surface including multiple contacts coupled to the first thermally conductive component.

23. The method of claim 19, wherein the dielectric material includes a build-up film, and wherein the multi-layer substrate is not a printed circuit board (PCB).
